(19) United States
(12) Patent Application Publication
(10) Pub. No.: US 2026/0051466 A1
(43) Pub. Date: Feb. 19, 2026

(54) PLASMA PROCESSING SYSTEM WITH CONTINUOUS BIAS POWER AND SOURCE POWER

(71) Applicant: Tokyo Electron Limited, Tokyo (JP)

(72) Inventor: Jon-L INNOCENT-DOLOR, Kurokawa-gun (JP)

(21) Appl. No.: 18/806,542

(22) Filed: Aug. 15, 2024

(51) Int. Cl. H01J 37/32

(52) U.S. Cl. CPC H01J 37/32706; H01J 37/32715; H01J 2237/334

(57) ABSTRACT

A plasma processing system includes a chamber configured to house plasma in a process space; a wafer holder configured to place a structure in the chamber, wherein the structure is configured to be etched by the plasma; a first chamber component arranged on a first side of the wafer holder and is applied with a first signal; and a second chamber component arranged on a second side of the wafer holder and is applied with a second signal, the second side opposite to the first side. The first signal is associated with a first constant frequency, and the second signal is associated with a second constant frequency.

This disclosure relates to semiconductor processing technology, and more particularly, to apparatus and methods for performing a plasma-assisted process with continuous source power and bias power.

### BACKGROUND

In manufacturing semiconductor devices, plasma-assisted etching processes, which, for example, utilize plasma to etch a layer through a resist mask, are often used for forming a predetermined pattern on a predetermined layer disposed on a target substrate or semiconductor wafer.

### SUMMARY

Embodiments herein describe plasma processing systems and methods of using the same. At least one aspect of the present disclosure is directed to a plasma processing system that includes a chamber configured to house plasma in a process space; a wafer holder configured to place a structure in the chamber, wherein the structure is configured to be etched by the plasma; a first chamber component arranged on a first side of the wafer holder and is applied with a first signal; and a second chamber component arranged on a second side of the wafer holder and is applied with a second signal, the second side opposite to the first side. The first signal is associated with a first constant frequency, and the second signal is associated with a second constant frequency.

In some embodiments, the first signal operatively serves as a source power for generating the plasma, and the second signal operatively serves as a bias power for generating the plasma.

In some embodiments, the first chamber component operatively serves as a top electrode for generating the plasma, and the second chamber component operatively serves as a bottom electrode for drawing ions in the process space.

In some embodiments, the first constant frequency is higher the second constant frequency.

In some embodiments, the second constant frequency is lower than 200 kHz.

In some embodiments, the second signal includes a negative voltage with the second constant frequency. The second signal has a ratio of activating the negative voltage to deactivating the negative voltage. The ratio is less than 10%.

In some embodiments, neither the first signal nor the second signal is modulated.

Another aspect of the present disclosure is directed to a plasma processing system. The plasma processing system includes a chamber configured to house plasma in a process space; a wafer holder configured to place a structure in the chamber, wherein the structure is configured to be etched by the plasma; a first electrode arranged over the wafer holder and is applied with a first signal having a first constant frequency; and a second electrode arranged beneath the wafer holder and is applied with a second signal having a second constant frequency. The second constant frequency is lower than the first constant frequency.

In some embodiments, the first signal operatively serves as a source power for generating the plasma, and the second signal operatively serves as a bias power for drawing ions in the process space.

In some embodiments, the second constant frequency is lower than 200 kHz.

In some embodiments, the second signal includes a negative voltage with the second constant frequency.

In some embodiments, the second signal has a ratio of activating the negative voltage to deactivating the negative voltage. The ratio is less than 10%.

In some embodiments, neither the first signal nor the second signal is modulated.

In some embodiments, the second constant frequency is 160 kHz.

Yet another aspect of the present disclosure is directed to a method for etching a semiconductor device. The method includes placing a semiconductor device on a wafer holder; generating plasma over the wafer holder through a first electrode, wherein the first electrode is applied with a first signal having a first constant frequency; drawing ions to the wafer holder through a second electrode, wherein the second electrode is applied with a second signal having a second constant frequency; and etching the semiconductor device using the plasma.

In some embodiments, the second constant frequency is substantially lower than the first constant frequency.

In some embodiments, the first electrode is arranged above the wafer holder, and the second electrode is arranged beneath the wafer holder.

In some embodiments, the second signal has a ratio of activating the negative voltage to deactivating the negative voltage, and the ratio is less than 10%.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a schematic diagram of a plasma processing system, according to various embodiments.

FIG. 2 illustrates example waveforms of a source power and a bias power applied to the plasma processing system of FIG. 1, respectively, according to various embodiments.

FIG. 3 illustrates a flow chart of an example method for operating the plasma processing system of FIG. 1, according to various embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections, and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

The fabrication of integrated circuits (IC) in the semiconductor industry typically employs plasma to create and assist surface chemistry within a vacuum processing system to remove material from or deposit material on a substrate. In general, plasma is formed within the processing system under vacuum conditions by heating electrons to energies sufficient to sustain ionizing collisions with a supplied process gas. Moreover, the heated electrons can have energy sufficient to sustain dissociative collisions and, therefore, a specific set of gases under predetermined conditions (e.g., chamber pressure, gas flow rate, etc.) are chosen to produce a population of charged species and chemically reactive species suitable to the particular process being performed within the system (e.g., etching processes where materials are removed from the substrate or deposition processes where materials are added to the substrate).

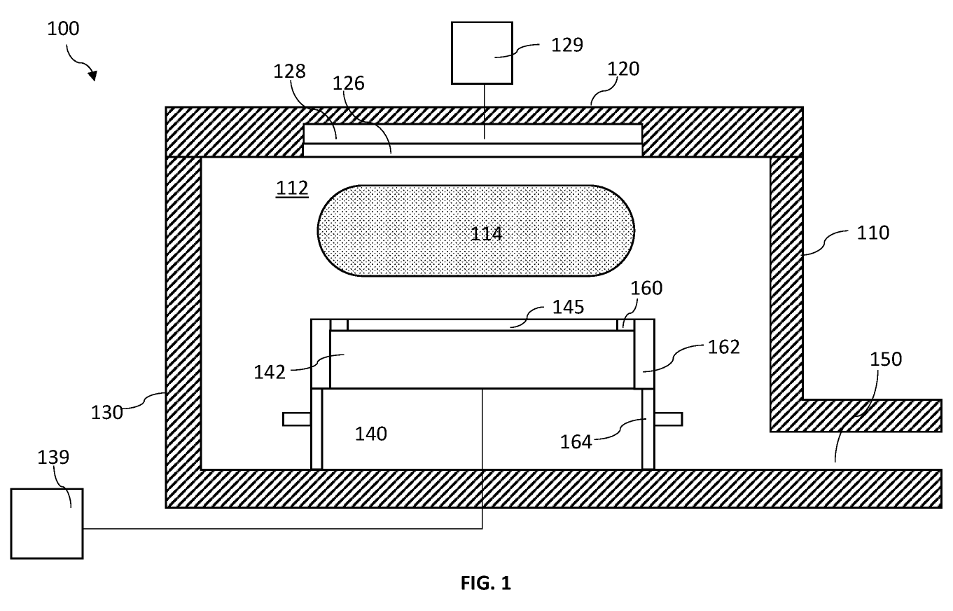

FIG. 1 illustrates a plasma processing system 100, in accordance with various embodiments of the present disclosure. The plasma processing system 100 is configured to perform a plasma-assisted process on a substrate. For example, the plasma processing system 100 can etch a semiconductor device using plasma generated by the plasma processing system 100. However, it should be understood that the plasma processing system 100 is not limited to performing an etching process, and can perform other suitable semiconductor-related process while remaining within the scope of the present disclosure.

As shown, the plasma processing system 100 includes a plasma processing chamber 110, an upper assembly 120, a side assembly 130, a substrate holder 140 for supporting a substrate 145, and a pumping duct 150 coupled to a vacuum pump (not shown) for providing a reduced pressure atmosphere in the plasma processing chamber 110. The plasma processing chamber 110 can facilitate the formation of plasma 114 in a process space 112 adjacent the substrate 145. For example, the plasma 114 may be generated above the substrate 145. The generated plasma 114 can be utilized to create materials specific to a pre-determined materials process, and/or to aid the removal of material from the exposed surfaces of substrate 145. The plasma processing system 100 may be configured to process substrates of any size, such as 200 mm substrates, 300 mm substrates, 450 mm substrates, or larger. For example, the plasma processing system 100 may comprise a plasma etching system.

In the illustrative embodiment of FIG. 1, the upper assembly 120 may include an upper electrode vertically opposite to the top surface of the substrate 145. For example, the upper assembly 120 can include an upper electrode plate 126 and an upper electrode 128. In some embodiments, the upper electrode 128 may be electrically coupled to a first or upper power supply 129, and the upper electrode plate 126 may be composed of a material compatible with plasma in the process space 112. The first power supply 129 can generate or otherwise output a first signal (e.g., power) with a high frequency suitable for plasma generation. The first signal may sometimes be referred to as a source power for generating plasma, e.g., 114. The source power can be applied to the upper electrode 128. Although not shown, the first power supply 129 can be operatively coupled to the upper electrode 128 though a matching device and a power supply rod, which constitute a part of a high-frequency transmission path for sending the high-frequency source power to the upper electrode 128. The first power supply 129 may further include a system configured to perform at least one of monitoring, adjusting, or controlling the polarity, current, voltage, or on/off state of the first signal (e.g., the source power).

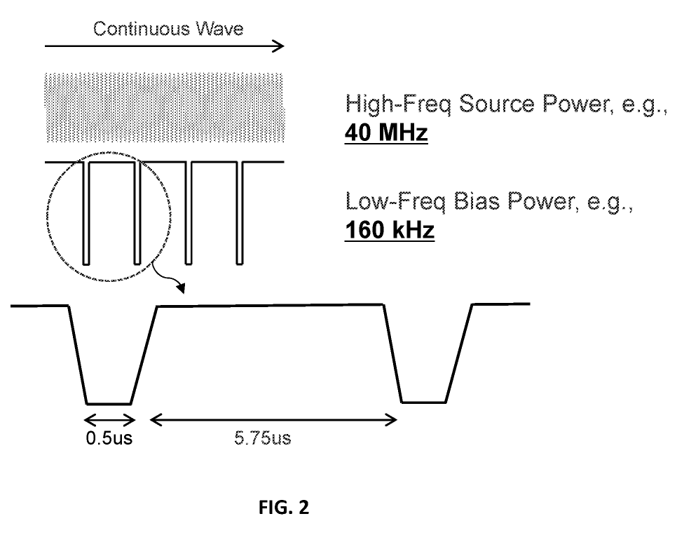

In various embodiments of the present disclosure, the source power applied to the upper electrode 128 may be provided as a continuous power, which is further illustrated in FIG. 2. Stated another way, the source power may not be modulated by any pulse signal. As a non-limiting example, the source power may be provided with a high frequency of about 40 MHz and with an average power of about 1.92 kW.

Although not shown, it should be understood that the upper assembly 120 can include a gas buffer room formed therein. The upper assembly 120 can further include, in its bottom surface, a multiple number of gas holes extended from the gas buffer room, and the gas holes communicate with gas discharge holes formed along the upper electrode plate 126, respectively. The gas buffer room can be connected to a processing gas supply source via a gas supply line. The processing gas supply source is provided with a mass flow controller (MFC) and an opening/closing valve. If a certain processing gas (etching gas) is introduced into the gas buffer room from the processing gas supply source, the processing gas is then discharged in a shower shape from the gas discharge holes of the upper electrode plate 126 into the process space 112 toward the substrate 145. In such a configuration, the upper electrode 128 and/or the upper electrode plate 126 can sometimes serve as a part of the shower head that supplies the processing gas into the process space 112.

The substrate holder 140 can include a focus ring 160, a shield ring 162, and a bellows shield 164. The focus ring 160 may be interposed between the substrate 145 and the shield ring 162. The focus ring 160 may be removably fastened to the substrate holder 140. The substrate 145 can be affixed to the substrate holder 140 via a clamping system (not shown), such as a mechanical clamping system or an electrical clamping system (e.g., an electrostatic clamping system). Furthermore, the substrate holder 140 can include a heating system (not shown) or a cooling system (not shown) that is configured to adjust and/or control a temperature of the substrate holder 140 and the substrate 145. The heating system or cooling system may comprise a re-circulating flow of heat transfer fluid that receives heat from the substrate holder 140 and transfers heat to a heat exchanger system (not shown) when cooling, or transfers heat from the heat exchanger system to the substrate holder 140 when heating. Alternatively or additionally, heating/cooling elements, such as resistive heating elements, or thermo-electric heaters/coolers can be included in the substrate holder 140, as well as the chamber wall of the plasma processing chamber 110 and any other component within the plasma processing system 100.

The substrate holder 140 can further include a substrate holder or lower electrode 142 operatively coupled to a second or lower power supply 139. The second power supply 139 can generate or otherwise output a second signal (e.g., power) with a low frequency (compared to the frequency generated by the first power supply 129) suitable for drawing ions in the process space 112. The second signal may sometimes be referred to as a bias power for drawing ions generated during the generation of plasma 114. The bias power, which is provided with an oscillating negative voltage, can be applied to the lower electrode 142. Although not shown, the second power supply 139 can be operatively coupled to the lower electrode 142 though a matching device and a power supply rod, which constitute a part of a low-frequency transmission path for sending the low-frequency source power to the lower electrode 142. The second power supply 139 may further include a system configured to perform at least one of monitoring, adjusting, or controlling the polarity, current, voltage, or on/off state of the second signal (e.g., the bias power).

In various embodiments of the present disclosure, the bias power applied to the lower electrode 142 may be provided as a continuous power, which is further illustrated in FIG. 2. Stated another way, the bias power may not be modulated by any pulse signal. As a non-limiting example, the bias power may be provided with a low frequency of about 160 kHz.

In some embodiments, each of these upper and lower electrodes may sometimes be referred to as a chamber component. Further, a pair of the chamber components are arranged along opposite edges of the process space 112, respectively. For example, the upper electrode 128 and the lower electrode 142 may be arranged along an upper edge and a lower edge of the process space 112, respectively. In some embodiments, the upper electrode 128 and the lower electrode 142 can each be formed as a multi-piece structure or a single-piece structure. In the example where the electrode 128/142 is formed as a multi-piece structure, different pieces can be electrically coupled to respective power signals.

In some embodiments, an etching process can be performed in the plasma processing chamber 110. For example, a processing gas for etching is supplied from a process gas supply source into the plasma processing chamber 110 at a predetermined flow rate through one or more gas flow channels and one or more gas delivery holes. At the same time, the interior of the plasma processing chamber 110 is exhausted by an exhaust unit to set the pressure inside the plasma processing chamber 110 to be a predetermined value within a range of, e.g., 0.1 to 150 Pa. The process gas may be selected from various gases, e.g., a gas containing a halogen element, a representative example of which is a fluorocarbon gas (CₓF_{y}), such as C₄F₈ gas. Further, the process gas may contain another gas, such as Ar gas or O₂ gas.

FIG. 2 illustrates non-limiting example waveforms of the first signal (source power) and the second signal (bias power) applied to the upper electrode 128 and the lower electrode 142, respectively, in accordance with some embodiments. As shown, the source power and the bias power are each provided a continuous wave, e.g., not further modulated by a pulse signal. Alternatively stated, as long as the etching process is performed by the plasma processing system 100, these two power signals are continuously provided to the upper electrode 128 and the lower electrode 142, respectively. In some embodiments, the source power is provided with a high frequency, e.g., 40 MHz, while the bias power is provided with a low frequency, e.g., 160 kHz. Further, the bias power may be provided with an extended off time. For example, as shown in FIG. 2, the bias power is activated/on (e.g., provided at a low voltage level) for about 0.5 μs, while being deactivated/off for about 5.75 μs. In some embodiments, a ratio of the activated time duration to the deactivated time period may be set below 10%, e.g., about 8%.

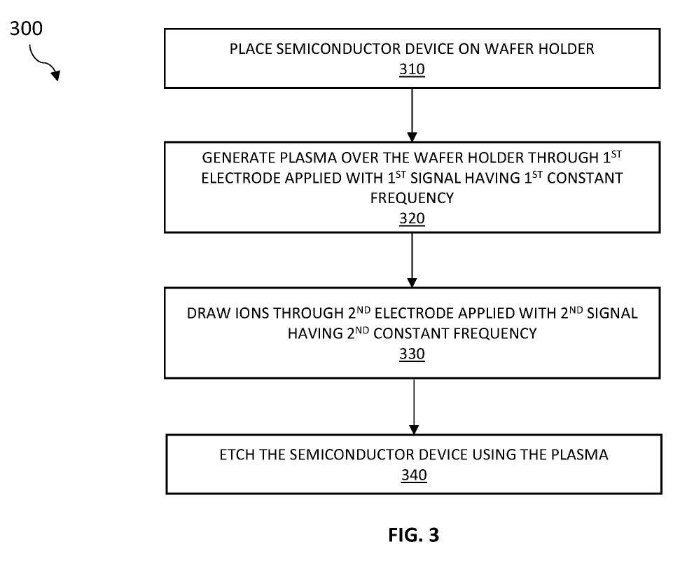

FIG. 3 illustrates a flow chart of an example method 300 for operating a plasma processing system, in accordance with various embodiments. For example, the method 300 may be performed to operate the plasma processing system 100, and thus, some of the reference numerals of FIGS. 1-2 may be reused in the following discussion of the method 300. One or more operations of the method 300 may be omitted, added, modified, or combined. The operations of the method 300 may be performed sequentially or concurrently. The operations of the method 300 can be performed in other order or sequence, not limited to those described herein.

The method 300 may start with operation 310 of placing a semiconductor device on a wafer holder. For example, the semiconductor device (e.g., 145), which may have a number of profiles with a high aspect ratio to be etched, may be placed on the wafer holder 140. It should be understood that such semiconductor devices are not limited to a 3D NAND memory device.

The method 300 may proceed to operation 320 of generating plasma over the wafer holder through a first electrode applied with a first signal having a first constant frequency. For example, the plasma (e.g., 114) can be generated in the process space 112 over the wafer holder 140 or over the semiconductor device 145. In some embodiments, the first electrode (e.g., 128) is applied with a source power, and the source power is associated with a high constant frequency. For example, the source power may not be modulated with any other pulse signal.

The method 300 may proceed to operation 330 of drawing ions (e.g., generated in the process space) through a second electrode applied with a second signal having a second constant frequency. In some embodiments, the second electrode (e.g., 142) is applied with a bias power, and the bias power is associated with a low constant frequency. For example, the bias power may not be modulated with any other pulse signal.

The method 300 may then proceed to operation 340 of etching the semiconductor device using the plasma generated.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A plasma processing system, comprising:
a chamber configured to house plasma in a process space;
a wafer holder configured to place a structure in the chamber, wherein the structure is configured to be etched by the plasma;
a first chamber component arranged on a first side of the wafer holder and is applied with a first signal; and
a second chamber component arranged on a second side of the wafer holder and is applied with a second signal, the second side opposite to the first side,
wherein the first signal is associated with a first constant frequency, and the second signal is associated with a second constant frequency.

2. The plasma processing system of claim 1, wherein the first signal operatively serves as a source power for generating the plasma, and the second signal operatively serves as a bias power for generating the plasma.

3. The plasma processing system of claim 1, wherein the first chamber component operatively serves as a top electrode for generating the plasma, and the second chamber component operatively serves as a bottom electrode for drawing ions in the process space.

4. The plasma processing system of claim 1, wherein the first constant frequency is higher the second constant frequency.

5. The plasma processing system of claim 1, wherein the second constant frequency is lower than 200 kHz.

6. The plasma processing system of claim 1, wherein the second signal includes a negative voltage with the second constant frequency.

7. The plasma processing system of claim 6, wherein the second signal has a ratio of activating the negative voltage to deactivating the negative voltage.

8. The plasma processing system of claim 7, wherein the ratio is less than 10%.

9. The plasma processing system of claim 1, wherein neither the first signal nor the second signal is modulated.

10. A plasma processing system, comprising:
a chamber configured to house plasma in a process space;
a wafer holder configured to place a structure in the chamber, wherein the structure is configured to be etched by the plasma;
a first electrode arranged over the wafer holder and is applied with a first signal having a first constant frequency; and
a second electrode arranged beneath the wafer holder and is applied with a second signal having a second constant frequency,
wherein the second constant frequency is lower than the first constant frequency.

11. The plasma processing system of claim 10, wherein the first signal operatively serves as a source power for generating the plasma, and the second signal operatively serves as a bias power for drawing ions in the process space.

12. The plasma processing system of claim 10, wherein the second constant frequency is lower than 200 kHz.

13. The plasma processing system of claim 10, wherein the second signal includes a negative voltage with the second constant frequency.

14. The plasma processing system of claim 13, wherein the second signal has a ratio of activating the negative voltage to deactivating the negative voltage.

15. The plasma processing system of claim 14, wherein the ratio is less than 10%.

16. The plasma processing system of claim 10, wherein neither the first signal nor the second signal is modulated.

17. The plasma processing system of claim 10, wherein the second constant frequency is 160 kHz.

18. A method for etching a semiconductor device, comprising:
generating plasma over a semiconductor device on a wafer holder through a first electrode, wherein the first electrode is applied with a first signal having a first constant frequency;
drawing ions to the wafer holder through a second electrode, wherein the second electrode is applied with a second signal having a second constant frequency; and
etching the semiconductor device using the plasma.

19. The method of claim 18, wherein the second constant frequency is lower than the first constant frequency.

20. The method of claim 18, wherein the first electrode is arranged above the wafer holder, and the second electrode is arranged beneath the wafer holder.

21. The method of claim 18, wherein the second signal has a ratio of activating the negative voltage to deactivating the negative voltage, and the ratio is less than 10%.
